(19) United States
(12) Patent Application Publication
(10) Pub. No.: US 2014/0273460 A1
(43) Pub. Date: Sep. 18, 2014

(54) PASSIVE CONTROL FOR THROUGH SILICON VIA TILT IN ICP CHAMBER

(71) Applicant: Applied Materials, Inc., Santa Clara, CA (US)

(72) Inventors: David REYLAND, San Francisco, CA (US); Dung Huu LE, San Jose, CA (US); Saravjeet SINGH, Santa Clara, CA (US); Madhava Rao YALAMANCHILI, Morgan Hill, CA (US)

(73) Assignee: APPLIED MATERIALS, INC., Santa Clara, CA (US)

(21) Appl. No.: 14/185,579

(22) Filed: Feb. 20, 2014

Related U.S. Application Data
(60) Provisional application No. 61/779,980, filed on Mar. 13, 2013.

(51) Int. Cl. H01L 21/311; H01L 21/768; H01L 21/687; H01L 21/67

(52) U.S. Cl. CPC H01L 21/31138; H01L 21/67069; H01L 21/76805; H01L 21/68735
USPC 438/694; 156/345.3; 156/345.29

(57) ABSTRACT

Embodiments of the present disclosure generally provide apparatus and methods for improving process result near the edge region of a substrate being processed. One embodiment of the present disclosure provides a cover ring for improving process uniformity. The cover ring includes a ring shaped body, and an extended lip extending radially inwards from the ring shaped body. An inner edge of the extended lip forms a central opening to expose a processing region on a substrate being processed, and a width of the extended lip is between about 15% to about 20% of a radius of the central opening.

### CROSS-REFERENCE TO RELATED APPLICATIONS

This application claims priority to U.S. Provisional Patent Application Ser. No. 61/779,980, filed on Mar. 13, 2013, which herein is incorporated by reference.

### BACKGROUND

1. Field

Embodiments of the present disclosure relate to apparatus and methods for processing semiconductor substrates. More particularly, embodiments of the present disclosure relate to apparatus and methods for improving process uniformity near an edge region of the substrate being processed.

2. Description of the Related Art

During manufacturing of semiconductor devices, a substrate is usually processed in a processing chamber, where deposition, etching, thermal processing may be performed to the substrate. Processing conditions, such as density, flow rate of processing gas or plasma, temperature, pressure, may vary within the processing chamber due to inherent factors, such as chamber geometry, external factors, such as magnetic field around the processing chamber, or processing parameters, such as flow rate, temperature. Different regions of the substrate being processed may be exposed to slightly different processing conditions causing undesirable processing result, such as non-uniformity across the substrate.

FIG. 1 is a schematic partial sectional view of a substrate 100 showing non-uniformity of a through silicon via (TSV) etching. A plurality of TSVs 108 are formed in a silicon layer 102 after an etching process. The TSVs 108 are high aspect ratio holes formed in the substrate 100. It is desirable to have the TSVs 108 formed perpendicular to a major surface 110 of the substrate 100. As shown in FIG. 1, the TSVs 108 near a central axis 104 of the substrate 100 have profiles that are substantially perpendicular to the major surface 110. However, TSVs 108a near an edge 106 of the substrate 100 have profiles that are tilted at an angle 112 relative to an imaginary line extending normal to the major surface 110. When the angle 112 reaches certain value, the TSV 108a become defective. In current TSV etching, manufacturers typically need to discard a 5 mm wide band from the edge 106 for a substrate sized in 300 mm in diameter due to the tilting of the TSVs 108a near the edge 106, wasting a substantial portion of the substrate.

Therefore, there is a need of apparatus and methods for improved process uniformity.

### SUMMARY

Embodiments of the present disclosure generally provide apparatus and methods for improving process result near the edge region of a substrate being processed.

One embodiment of the present disclosure provides a cover ring for improving process uniformity. The cover ring includes a ring shaped body, and an extended lip extending radially inwards from the ring shaped body. An inner edge of the extended lip forms a central opening to expose a processing region on a substrate being processed, and a width of the extended lip is between about 15% to about 20% of a radius of the central opening.

Another embodiment of the present disclosure provides a semiconductor processing chamber. The chamber includes a chamber body defining a processing volume, a substrate support disposed in the processing volume for supporting a substrate thereon, a plasma generator disposed outside the chamber body for generating a plasma within the processing volume, and a cover ring movably disposed over the substrate support for improving process uniformity. The cover ring includes a ring shaped body and an extended lip extending radially inwards from the ring shaped body. An inner edge of the extended lip forms a central opening to expose a processing region on the substrate supported by the substrate support, and a width of the extended lip is between about 15% to about 20% of a radius of the central opening.

Yet another embodiment of the present disclosure provides a method for processing a substrate support. The method includes positioning a substrate on a substrate support in a processing chamber, lowering a cover ring to the substrate support to cover an edge region of the substrate, and processing the substrate with one or more processing gases supplied to the processing chamber. The cover ring includes a ring shaped body, and an extended lip extending radially inwards from the ring shaped body. An inner edge of the extended lip forms a central opening to expose a processing region on the substrate supported by the substrate support, and a width of the extended lip is between about 15% to about 20% of a radius of the central opening.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic partial sectional view of a conventionally etched substrate showing TSV non-uniformity.

FIG. 2 is a schematic sectional view of a plasma processing chamber according to one embodiment of the present disclosure.

FIG. 3 is an enlarged view of a portion of the plasma processing chamber of FIG. 2.

FIG. 4 is a sectional perspective view of a cover ring according to one embodiment of the present disclosure.

FIG. 5 is schematic bottom view of a cover ring according to one embodiment of the present disclosure.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the present disclosure provide apparatus and methods for improving process uniformity near an edge region of the substrate being processed. More particularly, embodiments of the present disclosure provide a cover ring with an extended lip for improving processing uniformity near an edge region of a substrate being processed.

FIG. 2 is a schematic sectional view of a processing chamber 200 according to one embodiment of the present disclosure. The processing chamber 200 includes a cover ring 210 configured to improve TSV etch uniformity near an edge region 204 of a substrate 202 according to embodiment of the present disclosure. The processing chamber 200 may be configured to process a variety of substrates, such as semiconductor substrates and reticles, and accommodating a variety of substrate sizes.

The processing chamber 200 includes a chamber body 220 defining a processing volume 222. The chamber body 220 may include a bottom 224, sidewalls 226 and a lid 228 disposed over the sidewalls 226. A slit valve opening 230 is formed through the sidewall 226 to allow passage of the substrates and substrate transfer mechanism (not shown). A vacuum pump 232 is in fluid communication with the processing volume 222 and configured to maintain a low pressure environment within the processing volume 222. A plurality of nozzles 234 are positioned around an edge region of the processing volume 222. The plurality of nozzles 234 may be connected to a gas delivery system 236 and configured to inject one or more processing gases to the processing volume 222.

The processing chamber 200 may also include an antenna assembly 240 for generating a plasma inside the processing volume 222. In one embodiment, the antenna assembly 240 is disposed outside the chamber lid 228. The antenna assembly 240 may be coupled to a radio-frequency (RF) plasma power source 242 through a matching network 244. In the embodiment of FIG. 2, the antenna assembly 240 includes one or more solenoidal interleaved coil antennas disposed coaxially. Alternatively, the antenna assembly 240 may be other suitable arrangement.

A substrate support 250 is disposed in the processing volume 222. The substrate support 250 supports a substrate 202 during processing. A lift 252 may be coupled to lifting pins 254 to raise the substrate 202 from and to lower the substrate 202 down to the substrate support 250. The substrate support 250 may be an electrostatic chuck coupled to a chucking power source 256 to secure the substrate 202 thereon. In one embodiment, the substrate support 250 includes one or more embedded heating elements 258 coupled to a heating power source 260 for heating the substrate 202 during processing. The substrate support 250 further includes a bias electrode 262 coupled to a bias power source 264. The substrate support 250 may also include cooling channels 266 connected to a cooling fluid source 268 to provide cooling or heating and adjust temperature profile of the substrate 202 being processed.

The processing chamber 200 further includes an edge ring 216 disposed over the substrate support 250. The edge ring 216 surrounds a substrate supporting surface 270 of the substrate support 250 and forms a pocket around the substrate supporting surface 270 to receive the substrate 202 therein.

The cover ring 210 is movably disposed over the edge ring 216. During processing, the cover ring 210 rests on the edge ring 216 as shown in FIG. 1. In one embodiment, the cover ring 210 has a central opening 218 slightly smaller than an outer perimeter of the substrate 202 to cover an outer edge of the substrate 202 from the processing chemistry, such as plasma, in the processing volume 222. The geometry of the cover ring 210 and the position of the cover ring 210 relative to the substrate 202 provide improved process uniformity near the edge region 204 of the substrate during processing. For example, the cover ring 210 reduces the degree of tilting of TSVs near the edge of the substrate during TSV etching.

Three or more lift pins 214, one of which is shown in FIG. 2, driven by a lift 212 selectively raise the cover ring 210 from the edge ring 216. The lift pins 214 raise the cover ring 210 from the edge ring 216 to allow loading and unloading of the substrate 202 on the substrate support 250.

FIG. 3 is an enlarged view of a portion of the plasma processing chamber of FIG. 2 showing the cover ring 210 at a processing position. The cover ring 210 includes a ring shaped body 302 and an extended lip 304 extending inwardly from the ring shaped body 302. An inner edge 306 of the extended lip 304 bounds the inner circle 218 that exposes the substrate 202 to the processing volume 222. The inner edge 206 may be cylindrical. In one embodiment, the extended lip 304 is thinner than the ring shaped body 302. An upper surface 308 of the extended lip 304 is lower than an upper surface 316 of the ring shaped body 302. A slope 312 may connect the upper surface 308 of the extended lip 304 to the upper surface 316 of the ring shaped body 302. During processing, a lower surface 310 of the extended lip 304 rests on the edge ring 216 with an inner portion 320 overhanging above the edge ring 216. A plurality of recesses 314 may be formed on a lower surface 318 of the ring shaped body 302 to receive lift pins 214 for lifting the cover ring 210 up from the edge ring 216. An outward rim 330 may be formed in the backside of the cover ring 210, slanting downwards from the lower surface 310 of the extended lip 304 and the lower surface 318 of the ring shaped body 302. The outward rim 330 receives the edge ring 216 and may be used to facilitate alignment (i.e., centering) with the edge ring 216 when the cover ring 210 is being lowered to the edge ring 216.

Not to be bound by theory, the processing conditions, for example plasma density, flow rate, or pressure, around the edge region 204 of the substrate 202 may be different relative to the center of the processing volume 222 due to various conditions, such as chamber geometry, fluid dynamics in the processing chamber. The cover ring 210 improves processing uniformity around the edge region 204 of the substrate 202 by compensating the change in processing conditions near the edge region 204. The cover ring 210 may improve the processing uniformity around the edge region 204 of the substrate 202 by providing a wide and low step radially outwards from the edge region 204 of the substrate 202, such that the conditions in the center region of the processing volume 222 are extended outward as the outside diameter of the cover ring 210 effectively moves outward the effective edge of the substrate support 250.

The cover ring 210 may be formed from a material that is compatible with the processing chemistry. In one embodiment, the cover ring 210 may be formed from dielectric materials such as quartz, yttria (yttrium oxide), aluminum oxide. In one embodiment, the cover ring 210 is formed from aluminum oxide and is suitable for use in a TSV process, such as a process of alternating polymer deposition and silicon etch by plasma.

In one embodiment, the cover ring 210 provides a wide and low step with the extended lip 304. The upper surface 308 of the extended lip 304 may be substantially planar and having a lip width 326 and a lip height 324. As shown in FIG. 3, the extended lip 304 forms a low and wide step radially outward from a processing surface 202a of the substrate 202. In one embodiment, the lip width 326 may be about 15% to about 20% of the radius of the substrate 202 or the radius of the central opening 218. For example, the lip width 326 may be between about 22 mm to about 30 mm when the substrate 202 has a radius of about 150 mm. In one embodiment, the lip width 326 may be between about 24 mm to about 26 mm when the substrate 202 has a radius of about 150 mm. The lip height 234 may be between about 5% to about 15% of the lip width 326. In one embodiment, the lip height 234 may be between about 8% to about 9% of the lip width 326. For example, the lip height 324 may be between about 0.9 mm to about 3.0 mm when the lip width 326 is between about 24 mm to about 26 mm. In one embodiment, when the substrate 202 has a radius of about 150 mm, the lip width 326 may be between about 24 mm to about 26 mm and the lip height 324 may be between about 2.0 mm to about 2.30 mm.

As shown in FIG. 3, the central opening 218 of the cover ring 210 may be slightly smaller than the substrate 202 so that the cover ring 210 overlaps the substrate 202 at the edge region 204 by an overlap width 322 to protect the edge and backside side of the substrate 202 from the processing condition. The overlap width 322 may be less than 1.5 mm. The ratio of the overlap width 322 and the lip height 324 may be adjusted to improve process uniformity near the edge region 204. In one embodiment, the ratio of the overlap width 322 and the lip height 324 may be between about 0.5 to about 2.5. In another embodiment, the ratio of the overlap width 322 and the lip height 324 may be between about 1.7 to about 2.0. In one embodiment, the overlap width 322 may be less than about 1.2 mm while the lip height 324 is between about 2.0 mm to about 2.3 mm while the substrate 202 has a radius of about 150 mm. A small gap 328 may be presented between the backside 310 of the extended lip 304 and the processing surface 202a of the substrate 202 so that the cover ring 210 does not contact the substrate 202 during processing.

FIG. 4 is a sectional perspective view of the cover ring 210 while FIG. 5 is schematic bottom view of the cover ring 210. The central opening 218 may be circular. FIGS. 4-5 are provided to illustrate the sectional profile of the cover ring 210 and to illustrate the distribution of the three recesses 314 are around the ring shaped body 302.

Table 1 provides a set of result of tilting angle for a TSV process using cover rings according to embodiment of the present disclosure. The TSV process was achieved by performing rapid cycles of polymerization and silicon etching in a plasma processing chamber. For example, the polymerization process may include applying a polymer, such as trifluoromethane CHF₃, hexafluoropropene C₃F₆, octafluorocyclobutane C₄F₈, Hexafluoropropene C₃F₆, or octafluorocyclobutane C₄F₈. The silicon etching process may be performed using an etching gas containing SF₆.

The target through silicon vias are about 6 microns wide and about 50 microns deep. A cover ring similar to the cover ring 210 is used during the TSV process. The substrates being processed are 300 mm in diameter. The cover ring overlaps the substrates for about 1.2 mm at the edge. Cover rings of different ratio of lip height and lip width are used and the tilting angles near the edge region after etching shown in Table 1. A positive angle represents vias tilted such that the bottom of the via is pointed toward the edge of the substrate. A negative angle represents vias tilted such that the bottom of the via is pointed toward the center of the substrate. An angle of zero represents vias etched normal to the top surface of the substrate. As shown in Table 1, zero tilting angles are achieved well outside the 5 mm edge margin typically allowed in a TSV process. Therefore, embodiments of the present disclosure improve processing uniformity at the edge region, thus enlarging working area of each substrate and lowering cost of ownership for semiconductor manufacturers.

TABLE 1

| Ratio of Lip height 304/lip | Distance from Substrate Edge (mm) | | | | |
|---|---|---|---|---|---|
| width 326 | 1.5------------------>3.0---------------------->4.5 | | | | |
| 9.2% | 1.1° | 2.3° | 2° | 1.5° | 0° |
| 8.1% | 1.9° | 1.5° | <1° | 0° | 0° |
| 7.1% | 1.8° | 1.4° | <1° | 0° | 0° |
| 6.1% | −5.0° | <1° | <1° | 0° | 0° |
| 5.0% | −2.5° | <1° | 0° | 0° | 0° |

Even though a circular cover ring is described above, cover rings of different shapes, such as rectangular cover ring, may be used to achieve desired processing result when processing substrates of other shapes. Even though a TSV process are described above in association with embodiments of the present disclosure, embodiments of the present disclosure may be used in any processes wherein the processing environment near the edge region of the substrate being processed needs to adjusted to achieve a target process result, for example, to improve process uniformity near the edge region. Even though, the cover ring described above improves process uniformity near the edge region of the substrate, the cover ring may be used to achieve other processing results by adjusting the geometry and/or position of the cover ring. Other exemplary processing results may be edge thick or edge thin for deposition or etching.

While the foregoing is directed to embodiments of the present disclosure, other and further embodiments of the disclosure may be devised without departing from the basic scope thereof, and the scope thereof is determined by the claims that follow.

1. A cover ring for improving process uniformity, comprising:
a ring shaped body; and
an extended lip extending radially inwards from the ring shaped body, wherein an inner edge of the extended lip forms a central opening to expose a processing region on a substrate being processed, and a width of the extended lip is between about 15% to about 20% of a radius of the central opening.

2. The cover ring of claim 1, wherein a height of the extended lip is between about 5% to about 15% of the width of the extended lip.

3. The cover ring of claim 2, wherein a height of the extended lip is between about 8% to about 9% of the width of the extended lip.

4. The cover ring of claim 3, wherein the central opening is sized so that the cover ring and the substrate being processed overlaps at an edge region of the substrate when the substrate and the cover ring are concentrically position, and a ratio of an overlap width and the height of the extended lip is between about 0.5 to about 2.5.

5. The cover ring of claim 4, wherein the ratio of the overlap width and the height of the extended lip is between about 1.7 to about 2.0.

6. The cover ring of claim 1, wherein the cover ring is formed from aluminum oxide, quartz, or yttria.

7. The cover ring of claim 1, wherein the width of the extended lip is between about 24 mm and about 26 mm and the radius of the central opening is between about 148.5 mm to about 150 mm.

8. The cover ring of claim 7, wherein a height of the extended lip is between about 0.9 mm to about 2.5 mm.

9. The cover ring of claim 8, wherein the height of the extended lip is between about 2.0 mm to about 2.3 mm.

10. A semiconductor processing chamber, comprising:
a chamber body defining a processing volume;
a substrate support disposed in the processing volume for supporting a substrate thereon;
a plasma generator disposed outside the chamber body for generating a plasma within the processing volume; and
a cover ring movably disposed over the substrate support for improving process uniformity, wherein the cover ring comprises:
a ring shaped body; and
an extended lip extending radially inwards from the ring shaped body, wherein an inner edge of the extended lip forms a central opening to expose a processing region on the substrate supported by the substrate support, and a width of the extended lip is between about 15% to about 20% of a radius of the central opening.

11. The semiconductor processing chamber of claim 10, wherein a height of the extended lip is between about 5% to about 15% of the width of the extended lip.

12. The semiconductor processing chamber of claim 11, wherein a height of the extended lip is between about 8% to about 9% of the width of the extended lip.

13. The semiconductor processing chamber of claim 12, wherein the central opening is sized so that the cover ring and the substrate being processed overlaps at an edge region of the substrate when the substrate and the cover ring are concentrically position, and a ratio of an overlap width and the height of the extended lip is between about 0.5 to about 2.5.

14. The semiconductor processing chamber of claim 13, wherein the ratio of the overlap width and the height of the extended lip is between about 1.7 to about 2.0.

15. The semiconductor processing chamber of claim 10, wherein the cover ring is formed from aluminum oxide, quartz, or yttria.

16. The semiconductor processing chamber of claim 10, further comprising a lift that selectively raises or lowers the cover ring.

17. The semiconductor processing chamber of claim 16, further comprises a plurality of lift pins coupled to the lift, wherein the cover ring includes a plurality of recess formed on a backside for receiving the plurality of lift pins.

18. A method for processing a substrate support, comprising:
positioning a substrate on a substrate support in a processing chamber;
lowering a cover ring to the substrate support to cover an edge region of the substrate, wherein the cover ring comprises:
a ring shaped body; and
an extended lip extending radially inwards from the ring shaped body, wherein an inner edge of the extended lip forms a central opening to expose a processing region on the substrate supported by the substrate support, and a width of the extended lip is between about 15% to about 20% of a radius of the central opening; and
processing the substrate with one or more processing gases supplied to the processing chamber.

19. The method of claim 19, wherein processing the substrate comprises:
generating an inductively coupled plasma in the processing chamber; and
applying a bias power to an electrode in the substrate support.

20. The method of claim 19, wherein processing the substrate comprises alternately performing:
applying a polymer layer on the substrate, wherein the substrate includes a silicon layer having a patterned mask disposed thereon; and
etching the polymer layer and the silicon layer with a plasma.
